(19) United States
(12) Patent Application Publication
(10) Pub. No.: US 2024/0404859 A1
(43) Pub. Date: Dec. 5, 2024

(54) SUBSTRATE CORRECTION DEVICE, SUBSTRATE LAMINATION DEVICE, SUBSTRATE PROCESSING SYSTEM, SUBSTRATE CORRECTION METHOD, SUBSTRATE PROCESSING METHOD, AND SEMICONDUCTOR DEVICE MANUFACTURING METHOD

(71) Applicant: NIKON CORPORATION, Tokyo (JP)

(72) Inventors: Mikio USHIJIMA, Chofu-shi (JP); Hajime MITSUISHI, Yokohama-shi (JP); Yoshihiro MAEHARA, Tokyo (JP); Tomohiro CHIBA, Yokohama-shi (JP)

(73) Assignee: NIKON CORPORATION, Tokyo (JP)

(21) Appl. No.: 18/799,299

(22) Filed: Aug. 9, 2024

Related U.S. Application Data
(63) Continuation of application No. PCT/JP2023/003482, filed on Feb. 2, 2023.

(30) Foreign Application Priority Data
Feb. 10, 2022 (JP) 2022-019634

(51) Int. Cl. H01L 21/68; H01L 21/18; H01L 21/67; H01L 21/683; H01L 21/687; H01L 21/78; H01L 23/544

(52) U.S. Cl. CPC H01L 21/68; H01L 21/187; H01L 21/67259; H01L 21/6835; H01L 21/68735; H01L 21/78; H01L 23/544

(57) ABSTRACT

In a first aspect of the present invention, there is provided a substrate correction device which includes: an acquisition unit which acquires first information based on positional information of a plurality of alignment marks on a substrate, the alignment marks being measured externally; a stage which holds the substrate; a correction unit which corrects a misalignment between the substrate held by the stage, and another substrate to be bonded to the substrate; and a control unit which controls the correction unit based on the first information.

The contents of the following patent application(s) are incorporated herein by reference:
NO. 2022-019634 filed in JP on Feb. 10, 2022
NO. PCT/JP2023/003482 filed in WO on Feb. 2, 2023

### BACKGROUND

### 1. Technical Field

The present invention relates to a substrate correction device, a substrate lamination device, a substrate processing system, a substrate correction method, a substrate processing method, and a semiconductor device manufacturing method.

### 2. Related Art

Patent Document 1 discloses a lithography system including: a measurement device measuring positional information of a plurality of the marks on the substrate; and an exposure apparatus performing alignment measurement to measure positional information for part of marks selected from among the plurality of marks on the substrate, and performing exposure.

### PRIOR ART DOCUMENT

### Patent Document

Patent Document 1: International Publication No. WO 2016/136691

### BRIEF DESCRIPTION OF THE DRAWINGS

FIG. 1 is a diagram schematically showing a configuration of a substrate processing system 1000 in the present embodiment.

FIG. 2 is a schematic plan view of a wafer W in the present embodiment.

FIG. 3 is a flowchart showing an operation of the substrate processing system 1000 in the present embodiment.

FIG. 4 is a diagram schematically showing a configuration of a measurement device 100 in the present embodiment.

FIG. 5 is a schematic plan view of a lamination device 200 in the present embodiment.

FIG. 6 is a schematic diagram illustrating a measurement of the wafer W in which a part of a prealigner 500 is used in the present embodiment.

FIG. 7 is a schematic cross-sectional view of a wafer holder WH that holds an upper wafer W of two wafers W to be laminated in the lamination device 200 in the present embodiment.

FIG. 8 is a schematic cross-sectional view of a wafer holder WH that holds a lower wafer W of the two wafers W to be laminated in the lamination device 200 in the present embodiment.

FIG. 9 is a flowchart showing a procedure for laminating the wafers W to produce a laminated body 230 in the lamination device 200 in the present embodiment.

FIG. 10 is a diagram showing, together with a structure of a lamination unit 300 in the present embodiment, a state after the wafer holder WH holding the wafer W is imported to the lamination unit 300.

FIG. 11 is a diagram describing an operation of the lamination unit 300 in step S15 in the present embodiment.

FIG. 12 is a schematic cross-sectional view of the lamination unit 300 in a state in which the wafer W is aligned in the present embodiment.

FIG. 13 is a diagram showing states of the wafer W and the wafer holder WH in an aligned state in the present embodiment.

FIG. 14 is a schematic cross-sectional view of the lamination unit 300 in a state in which lamination of the wafers W is started in the present embodiment.

FIG. 15 is a diagram showing states of the wafer W and the wafer holder WH in a state in which the lamination is started in the present embodiment.

FIG. 16 is a diagram showing states of the wafer W and the wafer holder WH in a state in which the wafer W held by the wafer holder WH is released in the present embodiment.

FIG. 17 is a flowchart showing a procedure for calculating a correction amount of the wafer W in the present embodiment.

FIG. 18 is a diagram showing a schematic configuration of a nonlinear vector diagram 901 showing a nonlinear component of a distortion of the wafer W in the present embodiment.

FIG. 19 is a diagram showing a schematic configuration of a three-dimensional diagram 902 for correcting the nonlinear component of the distortion of the wafer W in the present embodiment.

FIG. 20 is a flowchart showing a procedure for laminating the wafers W in the present embodiment.

FIG. 21 is a schematic cross-sectional view of a substrate correction device 601 which can be used in a case of correcting the nonlinear component of the distortion of the wafer W in the present embodiment.

FIG. 22 is a schematic plan view of the substrate correction device 601 in the present embodiment, and is a diagram showing a layout of an actuator 612 in the substrate correction device 601.

FIG. 23 is a diagram describing an operation of the substrate correction device 601 in the present embodiment.

FIG. 24 is a flowchart showing a semiconductor device manufacturing method of a lamination type in the present embodiment.

### DESCRIPTION OF EXEMPLARY EMBODIMENTS

Hereinafter, the present invention will be described through embodiments of the invention. The embodiments described below are not intended to limit the invention within the scope of the claims. Not all combinations of features described in the embodiments are essential for the solution of the invention.

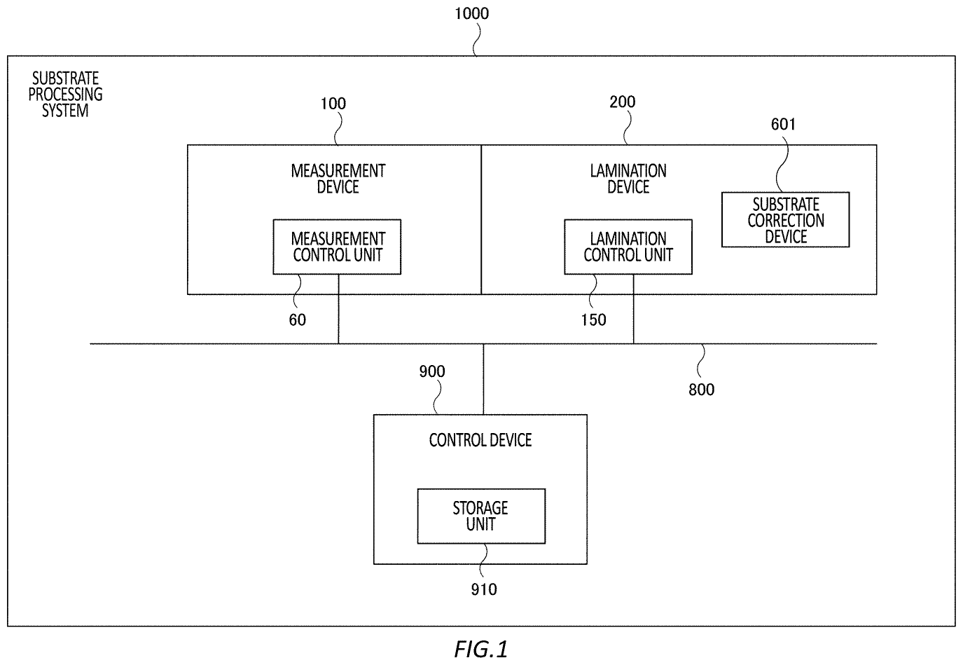

FIG. 1 is a diagram schematically showing a configuration of a substrate processing system 1000 in the present embodiment. As shown in FIG. 1, the substrate processing system 1000 includes a measurement device 100 and a lamination device 200 that are connected in-line to each other. It should be noted that being connected in-line means that different devices are connected to each other, in a state where a conveyance path for a wafer which is an example of a substrate, is connected. The measurement device 100 has a measurement control unit 60. The lamination device 200 includes a lamination control unit 150 and a substrate correction device 601.

The measurement control unit 60 included in the measurement device 100, and the lamination control unit 150 included in the lamination device 200 are connected to each other via a local area network (LAN) 800 and communicate with each other. A control device 900 which controls the entire substrate processing system 1000 is connected to the LAN 800. The control device 900 has a storage unit 910.

The substrate processing system 1000 in the present embodiment is a device which corrects a misalignment due to a distortion that occurs in the wafer, to laminate the wafers.

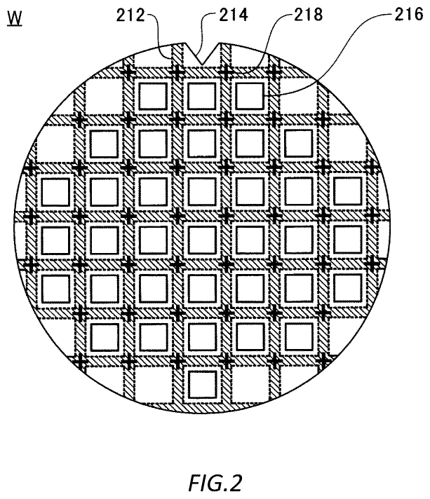

FIG. 2 is a schematic plan view of a wafer W to be laminated in the substrate processing system 1000. The wafer W has a notch 214, a plurality of circuit regions 216, and a plurality of alignment marks 218. The wafer W is, for example, a 300 mm wafer; and on the wafer W, a plurality of, for example, I circuit regions 216 (as an example, I=98) are formed in an arrangement of a matrix shape.

The circuit regions 216 are arranged on a front surface of the wafer W, periodically in a surface direction of the wafer W. In each of the circuit regions 216, a semiconductor device, wiring, a protective film, and the like are formed by a photolithography technique or the like. In the circuit region 216, a structural body including a connection unit such as a pad and a bump that serve as a connection terminal in a case of electrically connecting the wafer W to another wafer W, a lead frame, or the like, is also arranged.

The alignment mark 218 is an example of the structural body formed on the front surface of the wafer W, and is arranged to overlap a scribe line 212 arranged between the circuit regions 216. The alignment mark 218 is used as an indicator in a case of aligning this wafer W with another wafer W which is a target to be laminated. The alignment mark 218 includes, for example, an alignment mark for a search alignment, an alignment mark for a fine alignment, or the like. In the present embodiment, it is assumed that a two-dimensional mark is used as the alignment mark 218.

Subsequently, a type or the like of the distortion that occurs in the wafer W will be described. The distortion that occurs in the wafer W includes an initial distortion that occurs before the wafer W is laminated, and a distortion during the lamination, which occurs when the wafer W is laminated. The initial distortion is a distortion that occurs due to processing of the wafer W, such as forming the structural body on the front surface of the wafer W, and the distortion during the lamination is a distortion which occurs during a process of the lamination in the lamination device 200. In addition, the distortion that occurs in the wafer W is displacement of the structural body on the wafer W, from design coordinates, that is, a design position. The distortion that occurs in the wafer W includes a two-dimensional distortion and a three-dimensional distortion.

The two-dimensional distortion is a distortion that occurs in a direction along a lamination surface of the wafer W, and includes: a linear distortion in which the displaced position relative to the design position of the structural body in each of the wafers W, is represented by a linear transformation; and a nonlinear distortion which cannot be represented by the linear transformation, and is not the linear distortion.

The linear distortion includes a magnification distortion in which a displacement amount increases at a constant increase rate along a radial direction from the center. The magnification distortion is a value which is obtained by dividing a deviation amount from a design value at a distance of X from the center of the wafer W, by X, and of which a unit is ppm. The magnification distortion includes an isotropic magnification distortion. The isotropic magnification distortion is a distortion in which an X component and a Y component of a displacement vector from the design position are equal to each other, when the coordinates X and Y are the same value, that is, a magnification in an X direction and a magnification in a Y direction are equal to each other. An anisotropic magnification distortion that is a distortion in which the X component and the Y component of a displacement vector from the design position are different from each other, that is, the magnification in the X direction and the magnification in the Y direction are different from each other, is included in the linear distortion.

The linear distortion includes an orthogonal distortion. The orthogonal distortion is, when the X axis and the Y axis orthogonal to each other are set with an origin at the center of the wafer W, a distortion of displacement of the structural body in parallel to the X axis direction from the design position, and a distortion amount increases as the structural body is farther from the origin in the Y axis direction. The displacement amount is equal in each of a plurality of regions which cross the Y axis in parallel to the X axis, and the absolute value of the displacement amount increases as it is farther from the X axis. Further, in the orthogonal distortion, a direction of the displacement on a positive side of the Y axis and a direction of the displacement on a negative side of the Y axis are opposite to each other.

The three-dimensional distortion of the wafer W is a displacement in a direction other than the direction along the lamination surface of the wafer W, that is, in a direction intersecting the lamination surface. The three-dimensional distortion includes curving that occurs entirely or partially on the wafer W due to entire or partial bending of the wafer W. Here, the bending of the wafer W means that the wafer W changes to have a shape in such a manner that the front surface of the wafer W includes a point that does not exist on a plane specified by three points on the wafer W. The three-dimensional distortion also includes the linear distortion and the nonlinear distortion.

In addition, the curving is a distortion in which the front surface of the wafer W forms a curved surface, and includes, for example, a warpage of the wafer W. In the present embodiment, the warpage refers to a distortion remaining in the wafer W in a state in which an effect of gravity is eliminated. The distortion of the wafer W obtained by adding the effect of gravity to the warpage, is referred to as a deflection. It should be noted that the warpage of the wafer W includes: a global warpage in which the wafer W is entirely bent at a generally uniform curvature; and a local warpage in which a part of the wafer W is bent with a change in local curvature.

The nonlinear distortion occurs due to an interaction of effects of a wide variety of factors, and the main factors are crystal anisotropy in a silicon single crystal substrate, and a manufacturing process of the wafer W. In the manufacturing process of the wafer W, a plurality of structural bodies are formed on the wafer W. For example, the plurality of circuit regions 216, the scribe line 212, and the plurality of alignment marks 218 are formed on the wafer W as the structural body. As the structural body, in each of the plurality of circuit regions 216, wiring formed by a photolithography technique or the like, a protective film, and a connection unit such as a pad and a bump that serve as a connection terminal in a case of electrically connecting the wafer W to another wafer W, a lead frame, or the like, are also arranged. The structures or the arrangement of these structural bodies, that is, a configuration of the structural body, affects an in-plane stiffness distribution and an in-plane stress distribution of the wafer W, and when unevenness occurs in the stiffness distribution or the in-plane stress distribution, the curving occurs locally on the wafer W.

The configurations of these structural bodies may be different for each wafer W, or may be different for each type of the wafer W, such as a logic wafer, a CIS wafer, a memory wafer, or the like. In addition, even when the manufacturing process is the same, the configurations of the structural bodies can be considered to be somewhat different for each manufacturing device, and thus the configurations of those structural bodies may be different for each manufacturing lot of the wafer W. In this way, the configurations of the plurality of structural bodies formed on the wafers W may be different for each wafer W, the type of the wafer W, the manufacturing lot of the wafer W, or the manufacturing process of the wafer W. Therefore, the in-plane stiffness distributions of the wafers W are also similarly different from each other. Accordingly, the curved states of the wafers W which occur during the manufacturing process and the lamination process are also different from each other.

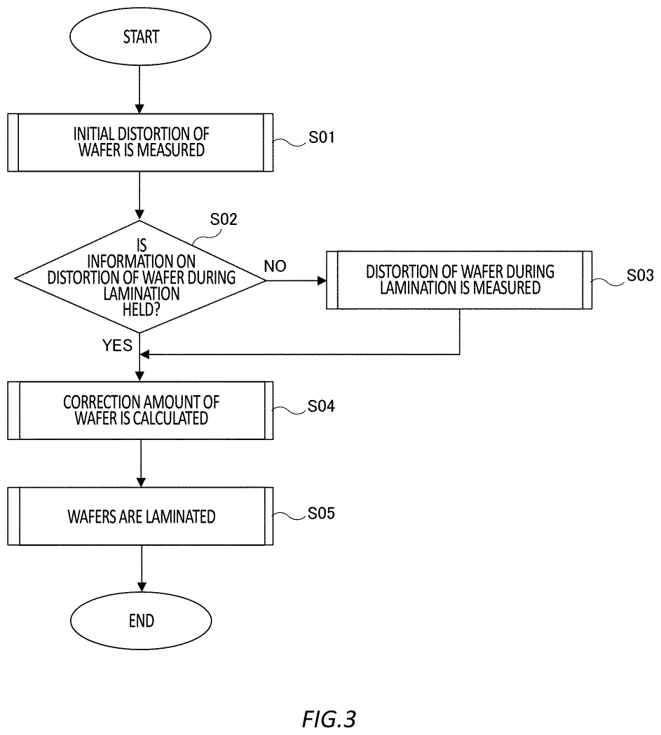

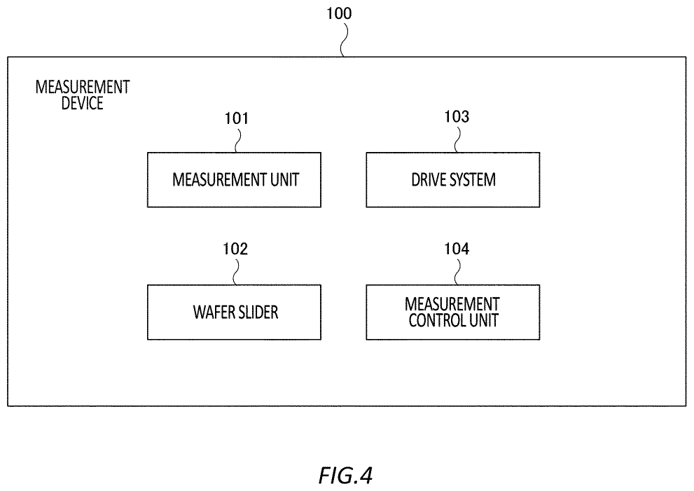

FIG. 3 is a flowchart showing an operation of the substrate processing system 1000 in the present embodiment. In step S01, the measurement device 100 measures the initial distortion that occurs before the lamination in the laminated wafers W. In step S02, it is determined regarding whether information on the distortion during the lamination, which occurs when the wafer W is laminated, is held. If the information on the distortion of the wafer W during the lamination is not held (NO in step S02), processing proceeds to step S03, and the distortion of the wafer W during the lamination is measured. After the step S03 is ended, the processing proceeds to step S04, and a correction amount of the wafer W is calculated. In step S02 of FIG. 3, if the information on the distortion of the wafer W during the lamination is held (YES in step S02), the processing proceeds to step S04 without going through step S03. After step S04 is ended, the processing proceeds to step S05, and the wafers W are laminated. Hereinafter, the details of step S01 in which the initial distortion of the wafer W is measured by the measurement device 100 will be described by using FIG. 4 to FIG. 8.

FIG. 4 is a diagram schematically showing a configuration of a measurement device 100 in the present embodiment. The measurement device 100 is a device which measures the plurality of alignment marks 218 on the wafer W, to measure the distortion of the wafer W. The measurement device 100 includes a measurement unit 101 having a mark detection system which detects the alignment mark 218 on the wafer W; a wafer slider 102 which holds the wafer W and is capable of a small movement relative to a stage on which the wafer W is placed; a drive system 103 which drives the wafer slider 102; and a measurement control unit 104 which acquires measurement information by the measurement unit 101 while controlling the drive of the wafer slider 102 by the drive system 103, and calculates positional information of a plurality of marks on the wafer W.

The measurement unit 101 detects, for example, one alignment mark 218 for each of a plurality of regions divided on the wafer, by using the mark detection system. In the present embodiment, the measurement unit 101 detects a first number of the alignment marks 218. The first number may be, for example, the number of all of the alignment marks 218 provided on the wafer W. That is, the measurement unit 101 may measure the positions of all of the alignment marks 218 provided on the wafer W. A plurality of measurement units 101 may be provided. The measurement control unit 104 calculates the positional information of each alignment mark 218, based on the measurement information by the measurement unit 101. The measurement control unit 104 performs an EGA (Enhanced Global Alignment) calculation by using the positional information of the alignment mark 218 measured by the measurement unit 101. The EGA calculation means a statistical calculation for calculating, after measuring the alignment mark 218, a parameter of a model expression that expresses the correction amount of the position coordinates of the alignment mark 218, by using a statistical calculation such as the least squares method, based on information on a difference between the design value and an actual measured value of the position coordinates of the alignment mark 218.

By calculating the result of the EGA calculation through the statistical calculation such as the least squares method, it is possible to accurately calculate a linear component and a nonlinear component of the initial distortion of the wafer W. The measurement control unit 104 transmits, to the control device 900, information on the calculated linear component and nonlinear component of the initial distortion of the wafer W. It should be noted that the measurement control unit 104 may transmit, to the control device 900, only information on the nonlinear component of the initial distortion of the wafer W.

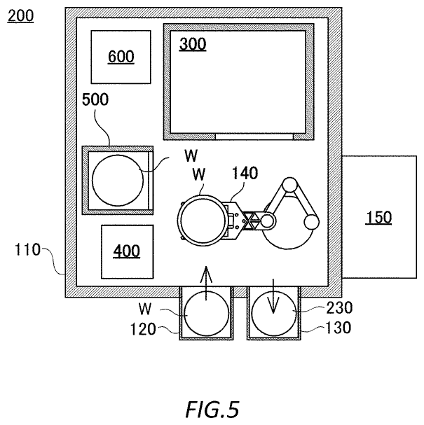

Hereinafter, the measurement of the distortion of the wafer W during the lamination in step S03 of FIG. 3 will be described in detail by using FIG. 5 to FIG. 16. FIG. 5 is a schematic plan view of the lamination device 200 in the present embodiment. The lamination device 200 is a device which laminates one wafer W to another wafer W to form a laminated body 230, and includes a housing 110, wafer cassettes 120, 130 arranged on an outside of the housing 110, a lamination control unit 150, a conveyance unit 140 arranged on an inside of the housing 110, a lamination unit 300, a holder stocker 400, a prealigner 500, and an activation device 600.

One wafer cassette 120 houses the wafers W to be laminated. Another wafer cassette 130 houses a plurality of laminated bodies 230 formed by laminating the wafer W. By using the wafer cassette 120, it is possible to collectively import a plurality of wafers W to the lamination device 200. In addition, by using the wafer cassette 130, it is possible to collectively export the plurality of laminated bodies 230 from the lamination device 200.

The conveyance unit 140 conveys the wafer W and a wafer holder WH from the measurement device 100 to the inside of the lamination device 200. The holder stocker 400 houses a plurality of wafer holders WH. The conveyance unit 140 imports, for setting, the wafer holder WH selected from the holder stocker 400 to the inside of the lamination unit 300 in advance, and then imports the wafer W to be laminated, to the lamination unit 300. The conveyance unit 140 may convey the wafer holder WH holding the wafer W, to the inside of the lamination unit 300.

The wafer holder WH is an example of a wafer holding member, and is a member that has a disk shape, a dimension slightly greater than that of the wafer W, and high stiffness. Each of the wafer holders WH has a wafer suction function of an electrostatic chuck, a vacuum chuck, or the like; and individually holds the wafer W inside the lamination device 200.

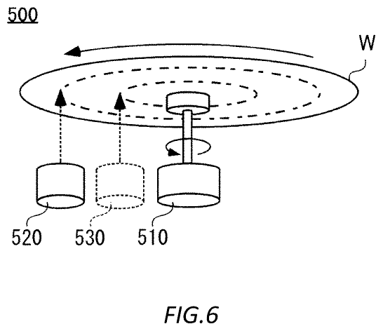

FIG. 6 is a schematic diagram illustrating a measurement of the wafer W in which a part of the prealigner 500 is used. The prealigner 500 includes a rotation drive unit 510, an edge detection unit 520, and a distance measurement unit 530.

The rotation drive unit 510 supports and rotates the mounted wafer W at a vicinity of the center thereof against gravity. The edge detection unit 520 continuously detects a position of an outer circumferential end portion of the wafer W which is rotating. In this manner, the prealigner 500 detects an eccentricity amount of the wafer W relative to the center of the rotation, and detects the geometric center of each wafer W. In addition, a notch or the like provided to the wafer W is detected, and an orientation of the wafer W is also detected.

The prealigner 500 measures deformation of the wafer W by using the distance measurement unit 530. The distance measurement unit 530 detects a distance to a lower surface of the wafer W which is rotating, in the figure, in a direction parallel to an axis of rotation. This makes it possible to continuously detect the deformation of the wafer W in a thickness direction, in a circumferential direction, based on the detected change in distance. Further, by causing the distance measurement unit 530 to perform scanning in the radial direction of the wafer W, it is possible to measure a state in relation to the deformation of the entire wafer W.

At this step, it may be determined that the wafer W in which the deformation greater than a predetermined range is detected, is not suitable for the lamination. The wafer W which is determined not to be suitable for the lamination may be conveyed to a predetermined position, for example, a specific housing position of the wafer cassette 130, and removed from the target to be laminated.

The determination to remove a certain wafer W from the target to be laminated, may be made, for example, based on the fact that a deformation amount of the wafer W exceeds a predetermined range. Here, exceeding the predetermined range means, for example, a case where the wafer W is deformed to a degree that the force of suction of the wafer holder WH which is a holding member, is not sufficient to press the wafer W tightly against a holding surface of the wafer holder WH.

In addition, exceeding the predetermined range means, for example, a case where the deformation amount of the wafer W which is the target to be measured, exceeds a limit of the correction amount by the correction described below. Further, exceeding the predetermined range means, for example, a case where when the combination of the wafer W which is the target to be measured, and the wafer W to be laminated thereon is already determined, the misalignment due to the difference in the deformation amount between the two wafers W, reaches a magnitude that cannot be eliminated by the correction described below. The correction amount refers to the deformation amount caused to occur on at least one of the two wafers W in such a manner that the misalignment between the two wafers W laminated on top of each other becomes smaller than or equal to a threshold value.

The lamination control unit 150 is constituted by a processor such as a CPU, a FPGA, or an ASIC, and a memory such as a ROM and a RAM; and causes each unit of the lamination device 200 to be linked to each other, and performs an overall control, based on a control program. In addition, the lamination control unit 150 receives an instruction from a user from the outside and sets a manufacturing condition for a case of manufacturing the laminated body 230. Further, the lamination control unit 150 also has a user interface for displaying, to the outside, an operating state of the lamination device 200.

The activation device 600 generates plasma for activating an upper surface of the wafer W. The wafers W activated by the activation device 600 are laminated by being brought into contact with or close to each other. It should be noted that the term “laminate” includes autonomous suction and bonding of the wafers W to each other. The activation device 600 activates the upper surface of the wafer W with the plasma, and then cleans the front surface of the wafer W with a chemical liquid such as ammonia, alcohol, or hydrochloric acid, or with pure water.

The lamination unit 300 has a pair of stages which respectively hold the wafers W and oppose each other; aligns the wafers W held by the stages with respect to each other; and then causes the wafers to be brought into contact with each other and laminated; and forms the laminated body 230.

The wafer W laminated in the lamination device 200 may be an unprocessed silicon wafer, a compound semiconductor wafer, a glass wafer, or the like, in addition to the wafer W on which the element, the circuit, the terminal, or the like is formed. In addition, the combination of the wafers W to be laminated may be for a circuit wafer and an unprocessed wafer, or for unprocessed wafers. Further, the wafers W to be laminated may themselves be a laminated body already formed by laminating the plurality of wafers.

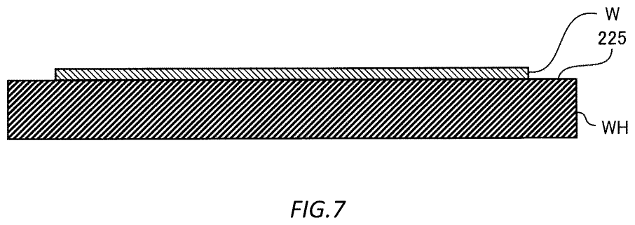

FIG. 7 is a schematic cross-sectional view of the wafer holder WH that holds an upper wafer W of the two wafers W to be laminated in the lamination device 200. The wafer holder WH has a holding surface 225 which is flat, and has a function of an electrostatic chuck, a vacuum chuck, or the like, which suctions and holds the wafer W. It should be noted that the wafer holder WH may have a holding surface with a convex shape in which the center is raised, or a holding surface that partially has a shape of a bump and an indentation.

As described below, one wafer W1 held by the wafer holder WH is released, at a step of being laminated on another wafer W. In the present embodiment, the one wafer W is held by the wafer holder WH having the holding surface 225 which is flat.

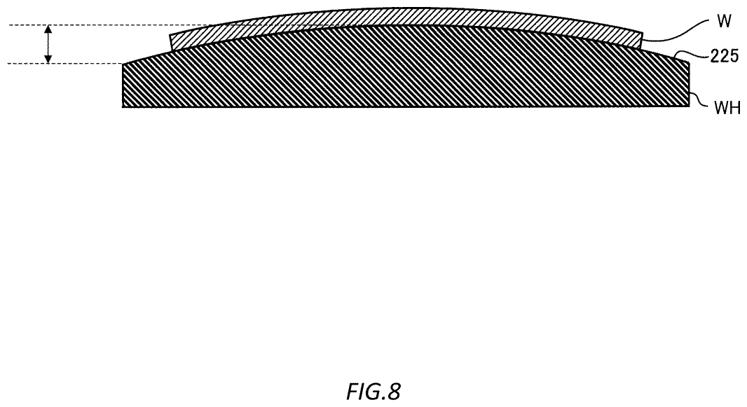

FIG. 8 is a schematic cross-sectional view of the wafer holder WH that holds a lower wafer W of the two wafers W to be laminated in the lamination device 200. In the illustrated example, the holding surface 225 of the wafer holder WH has a convex shape in which the center is raised.

The wafer holder WH has a function of an electrostatic chuck, a vacuum chuck, or the like, which suctions and holds the wafer W. Therefore, the wafer W held by the wafer holder WH is curved along the shape of the holding surface 225, and is deformed in a convex shape with the center of the wafer W as a local maximum.

As described above, it is possible to correct the linear distortion and nonlinear distortion that occur in the wafer W, by controlling the shape of the wafer holder WH which holds the wafer W. For example, for the wafer W on which the distortion of a magnification component that is the linear distortion, occurs, it is possible to perform the correction in which the magnification of the wafer W is changed by using the wafer holder WH having the holding surface 225 of a linearly curved surface with a uniform convex shape in the circumferential direction and deforming the wafer W suctioned by the wafer holder WH, as shown in FIG. 8.

Further, by using the wafer holder WH having the holding surface 225 of a partially concave or convex shape in the circumferential direction, it is possible to correct the nonlinear component of the distortion components that occur in the wafer W. In order to correct the nonlinear component, the wafer holder WH may have, for example, a concave shape in the vicinity of the center, or may have a shape in which the curvature in the vicinity of the center is smaller in comparison with that of another region.

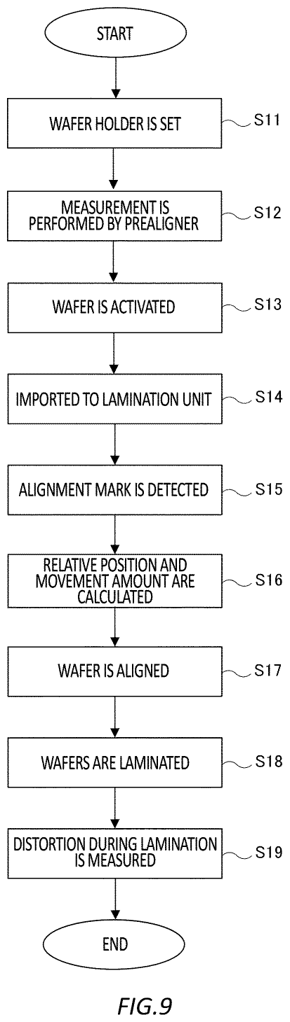

FIG. 9 is a flowchart showing a procedure (S03) for measuring the distortion of the wafer W during the lamination in the present embodiment.

The lamination control unit 150 selects the wafer holder WH from the holder stocker 400, and imports, by the conveyance unit 140, for setting, the selected wafer holder WH to the inside of the lamination unit 300 in advance (step S11). Subsequently, the lamination control unit 150 measures the deformation of the wafer W by using the distance measurement unit 530 of the prealigner 500 (step S12). Subsequently, the lamination control unit 150 activates the lamination surface in the wafer W to be laminated, and cleans the lamination surface of the wafer W (step S13). The lamination control unit 150 causes the front surface of the wafer W to be scanned with the plasma generated by the activation device 600. In this manner, each front surface of the wafer W is cleaned, and the chemical activity is increased. The wafers W are autonomously suctioned and laminated by being brought into contact with or close to each other.

It should be noted that in addition to a method of exposing the wafer W to the plasma, the wafer W can also be activated by sputter etching in which an inert gas is used, an ion beam, a high speed atom beam, or the like, or by mechanical processing such as polishing. When the ion beam or high speed atom beam is used, the lamination unit 300 is able to be generated under a reduced pressure.

Still further, the wafer W can also be activated by ultraviolet radiation, ozone asher, or the like. Further, for example, the activation is possible by chemically cleaning the front surface of the wafer W by using a liquid or a gas etchant.

Subsequently, the wafers W to be overlaid on each other are imported to the lamination unit 300 (step S14).

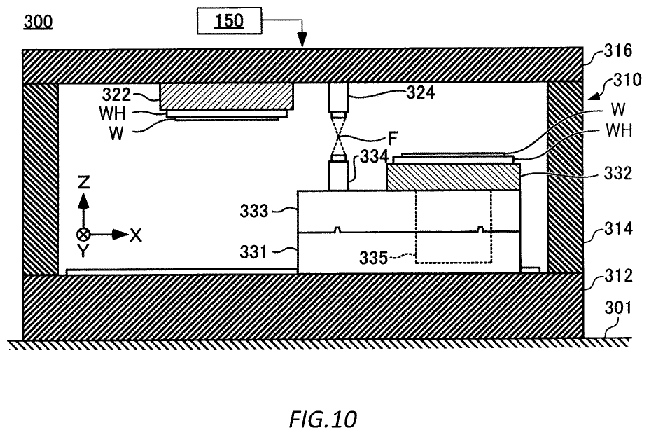

FIG. 10 is a diagram showing, together with a structure of a lamination unit 300 in the present embodiment, a state after the wafer W is imported to the lamination unit 300. The lamination unit 300 in the lamination device 200 includes a frame body 310, a fixed stage 322, and a moving stage 332 as a second stage.

The frame body 310 has a bottom plate 312 and a ceiling plate 316 which are parallel to a floor surface 301, and a plurality of support columns 314 which are perpendicular to the floor surface 301.

The fixed stage 322 which is fixed to a lower surface of the ceiling plate 316 in a downward direction in the figure, has a holding function of a vacuum chuck, an electrostatic chuck, or the like. As shown in the figure, on the fixed stage 322, the wafer W is held together with the wafer holder WH having the holding surface 225 which is flat.

A microscope 324 is fixed to the lower surface of the ceiling plate 316. The microscope 324 can observe the upper surface of the wafer W held by the moving stage 332 arranged opposite the fixed stage 322.

The moving stage 332 is mounted on a Y direction drive unit 333 that moves in a direction indicated by the arrow Y in the figure. The Y direction drive unit 333 is overlapped on an X direction drive unit 331 arranged on the bottom plate 312. The X direction drive unit 331 moves in a direction indicated by the arrow X in the figure, in parallel with the bottom plate 312. This makes it possible for the moving stage 332 to move two-dimensionally in the XY directions. The moving stage 332 shown in the figure holds the wafer W held by the wafer holder WH. Although not shown, the wafer holder WH has the holding surface 225 which is curved, and the wafer W is also held in a curved state along the holding surface 225.

It should be noted that the fixed stage 322 or the moving stage 332 on which the wafer W is placed in the lamination unit 300 of the lamination device 200, may directly hold the wafer W without using the wafer holder WH. In this case, the fixed stage 322 or the moving stage 332 serves as the holding member.

In addition, the moving stage 332 moves up and down relative to the Y direction drive unit 333, by a Z direction drive unit 335 which moves up and down in a direction indicated by the arrow Z.

A movement amount of the moving stage 332 by the X direction drive unit 331, the Y direction drive unit 333, and the Z direction drive unit 335 is precisely measured by using an interferometer or the like. In addition, the X direction drive unit 331 and the Y direction drive unit 333 may have two stage configurations of a coarse movement unit and a fine movement unit. In this manner, both of the alignment of a high precision, and high throughput are achieved, and the wafer W mounted on the moving stage 332 can be moved and laminated at high speed without reducing a control precision.

On the Y direction drive unit 333, each microscope 334 is further mounted beside the moving stage 332. The microscope 334 can observe the lower surface of the wafer W which is held by the fixed stage 322 in the downward direction.

It should be noted that the lamination unit 300 may further include a rotation drive unit which rotates the moving stage 332 around the axis of rotation which is perpendicular to the bottom plate 312, and a swing drive unit which swings the moving stage 332. This makes it possible to adjust a tilt angle of the moving stage 332; to set the moving stage 332 to be parallel to the fixed stage 322; to rotate the wafer W held by the moving stage 332; and to enhance the alignment precision of the wafer W.

The lamination control unit 150 calibrates the microscopes 324, 334 relative to each other in advance, by adjusting the focal points of the microscopes 324, 334 relative to each other, or by causing them to observe the common indicator. In this manner, the relative positions of the pair of the microscopes 324, 334 in the lamination unit 300 are measured. Next, referring back to FIG. 9, in the lamination unit 300, the alignment mark 218 formed on each of the wafers W is detected (step S15).

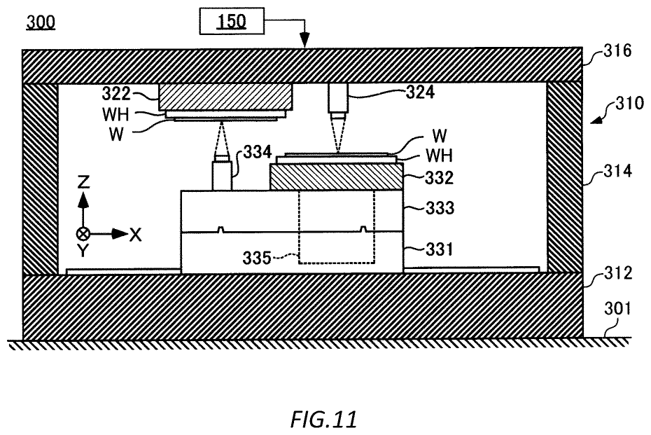

FIG. 11 is a diagram describing an operation of the lamination unit 300 in step S15. In step S15, the lamination control unit 150 causes the X direction drive unit 331 and the Y direction drive unit 333 to be operated, and causes a second number of the alignment marks 218 among the alignment marks 218 provided on each of the wafers W, to be detected by the microscopes 324, 334. The second number may be, for example, a number that is less than or equal to ten. In the present embodiment, by the positional information of the alignment mark 218 of the wafer W measured by the measurement device 100, it is possible to know in advance the linear distortion and the nonlinear distortion of the wafer W. Accordingly, in step S15, it is needed only to be able to secure the position of the wafer W relative to the coordinate system of the lamination unit 30, that is, the number of measurement points which is necessary to grasp the shift and the rotation; and accordingly the second number of the alignment marks 218 of the wafer W which are measured in step S15 may be less than the first number of the alignment marks 218 of the wafer W which are measured by the measurement device 100.

In this way, by detecting the positional information of the alignment mark 218 of the wafer W by the microscopes 324, 334 of which relative positions are known, the lamination control unit 150 calculates the relative position of the wafer W and calculates the movement amount of the moving stage 332 (step S16). That is, in the lamination unit 300, the movement amount of the moving stage 332 is calculated in such a manner that corresponding circuit regions 216 overlay each other. It should be noted that in a case where the moving stage 332 is tilted and the tilt angle needs to be adjusted, the lamination control unit 150 also calculates an adjustment amount of the tilt angle. As described above, the microscopes 324, 334 in the present embodiment function as a second measurement unit which outputs second information indicating the movement amount of the moving stage 332 to align the wafer W. The movement amount of the moving stage 332, which is calculated in step S16, can be calculated by executing the EGA calculations in which the positions of the plurality of alignment marks 218 of the wafer W are measured, at a plurality of points, and the statistical processing is performed.

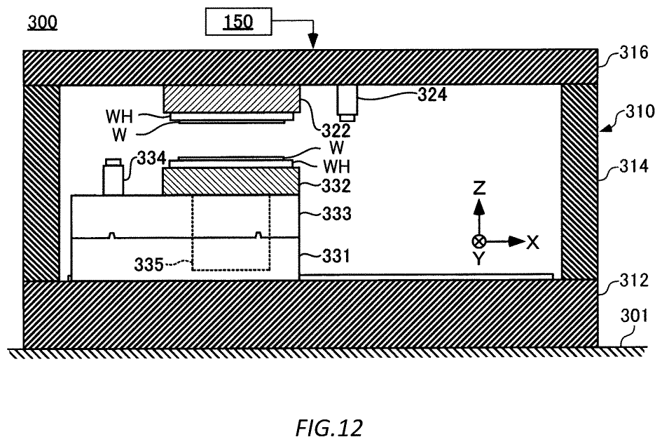

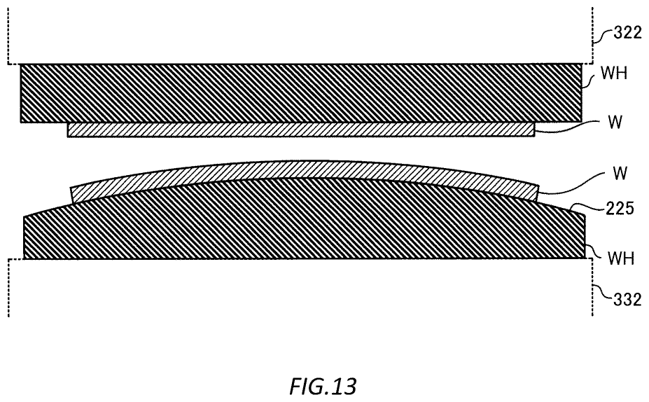

FIG. 9 is again referred to. Next, as shown in FIG. 12, the lamination control unit 150 causes the moving stage 332 to be moved, based on the movement amount calculated in step S15, and causes the wafer W to be aligned (step S17). FIG. 13 is a diagram showing states of the wafer W and the wafer holder WH in an aligned state.

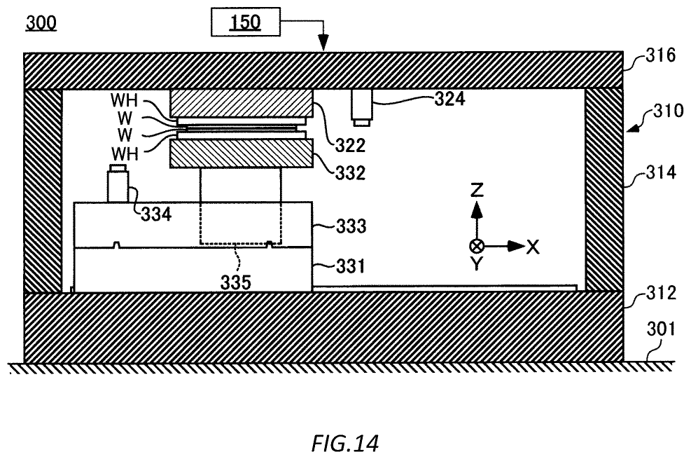

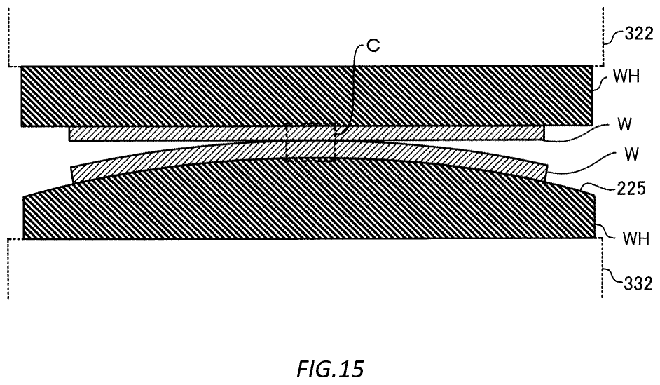

FIG. 9 is again referred to. Next, as shown in FIG. 14, the lamination control unit 150 causes the moving stage 332 to move up by the Z direction drive unit 335; causes the aligned wafers W to be brought into contact with each other; and starts laminating the wafers W (step S18). FIG. 15 is a diagram showing states of the wafer W and the wafer holder WH in a state in which the lamination is started.

As shown in FIG. 15, at a time of the contact in step S18, one wafer W which is flat and another wafer W which is curved are partially in contact with each other. In this manner, as shown by the dotted line C in the figure, a start point of laminating by which the wafers W are partially laminated, is formed approximately at the center of the wafer W.

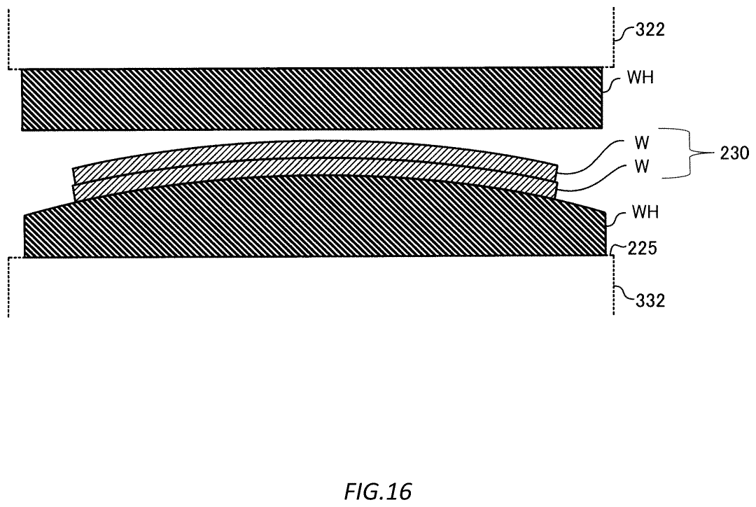

Subsequently, as shown in FIG. 16, after parts of the wafers W come into contact with each other, the lamination control unit 150 releases the wafer W held by the wafer holder WH on the fixed stage 322. The wafer W on an upper side in the figure, which is free in this manner, autonomously spreads a laminated region due to its own weight and the intermolecular force of the activated wafer W itself; and eventually becomes laminated over the entire surface. In this way, the laminated body 230 is formed by the wafers W in the lamination unit 300.

In the laminated body 230, the wafer W on a lower side in the figure continues to be held by the wafer holder WH in which the holding surface 225 is curved, through the lamination process from step S18 onwards. Therefore, the lamination is performed on the wafer W in a state in which the correction is made by the wafer holder WH, and thus a magnification difference between the wafers W or the like is corrected.

It should be noted that during the process in which the contact region of the wafer W is spreading as described above, the lamination control unit 150 may release a part or all of the wafer W held by the wafer holder WH. In addition, the wafer holder WH held by the fixed stage 322 may be released. When the held wafer W is released, during the process of spreading the contact region, the wafer W on the lower side rises up from the wafer holder WH and curved, due to the pulling force from the wafer W on the upper side. In this manner, the shape of the wafer W on the lower side is changed in such a manner that the front surface expands, and thus the difference in expansion amount from the front surface of the wafer W on the upper side, is reduced by this expansion amount.

Accordingly, the misalignment caused by the different deformation amount between the two wafers W is suppressed. A rising amount of the wafer W from the wafer holder WH can be adjusted, by adjusting the holding force of the wafer holder WH, and thus when a difference occurs between the correction amount preset for the plurality of wafer holders WH, and the correction amount that is actually required, it is possible to correct the difference by adjusting the holding force of the wafer holder WH.

Further, the lamination of the wafers W may be progressed by releasing the wafers W held by the moving stage 332 without releasing the wafers W held by the fixed stage 322. Further, the wafers W may be laminated by causing the fixed stage 322 and the moving stage 332 to be closer to each other while the wafers W are held by both of the fixed stage 322 and the moving stage 332.

When the laminated body 230 is formed by the wafers W, the microscopes 324,334 detect the plurality of alignment marks 218 formed on the wafers W which form the laminated body 230, and the positional information of the alignment marks 218 are acquired. By performing the EGA calculation based on the acquired positional information of the plurality of alignment marks 218 of the wafer W, it is possible to calculate the linear component and the nonlinear component of the distortion of the wafer W during the lamination (step S19). The positional information of the alignment mark 218 which is observed at this time includes the component of the initial distortion of the wafer W and the component of the distortion during the lamination, and thus it is possible to calculate the component of the distortion of the wafer W during the lamination, by subtracting the component of the initial distortion of the wafer W measured by the measurement device 100. The lamination control unit 150 transmits, to the control device 900, as third information, the information on the calculated linear component and nonlinear component of the distortion of the wafer W during the lamination. By the description above, the step of measuring the distortion of the wafer W during the lamination, in step S03 in FIG. 3, is ended.

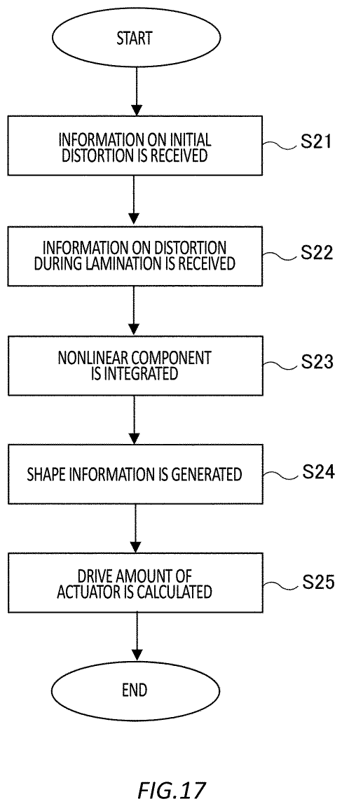

After step S03 in FIG. 3 is ended, the processing proceeds to step S04, and the correction amount of the wafer W is calculated. Hereinafter, the step of calculating the correction amount of the wafer W in step S04 of FIG. 3 will be described in detail by using FIG. 17 to FIG. 19.

FIG. 17 is a flowchart showing a procedure for calculating a correction amount of the wafer W in the present embodiment. FIG. 17 shows the details of step S04 in FIG. 3. In step S21 in FIG. 17, the control device 900 receives, from the measurement control unit 60, the information on the linear component and the nonlinear component of the initial distortion of the wafer W. Subsequently, in step S22, the control device 900 receives, from the lamination control unit 150, the information on the linear component and the nonlinear component of the distortion of the wafer W during the lamination.

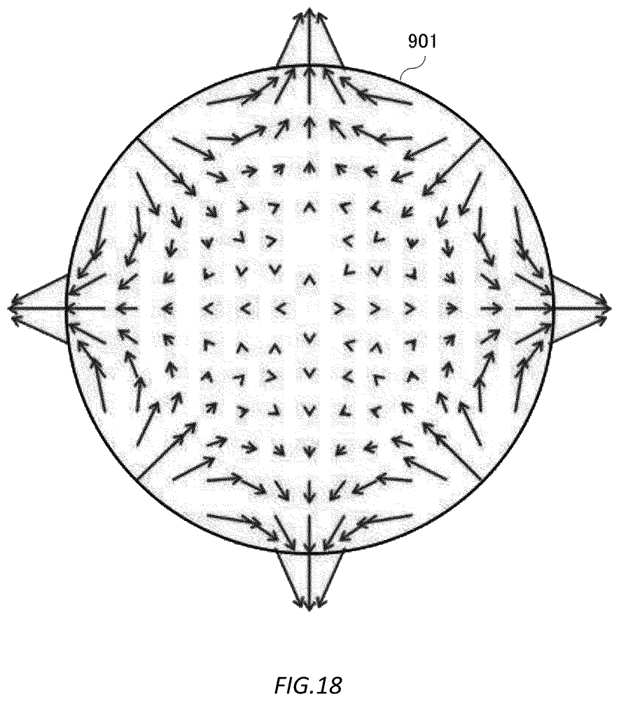

Subsequently, in step S23, by using the information on the nonlinear component of the initial distortion of the wafer W, the information on the nonlinear component of the distortion during the lamination, and the design information indicating the size of the wafer W, or the like, the control device 900 generates the information obtained by integrating the nonlinear component of the distortion of the wafer W. FIG. 18 is a nonlinear vector diagram 901 schematically showing information obtained by integrating the nonlinear component of the distortion of the wafer W in the present embodiment. FIG. 18 shows that in the wafer W, in a direction of the arrow, a distortion with a magnitude corresponding to a length of the arrow, occurs.

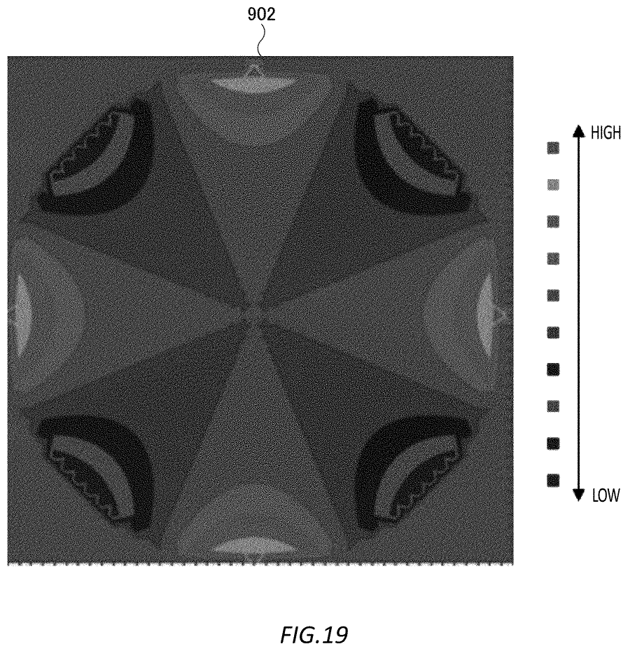

Subsequently, in step S24, the control device 900 generates the shape information indicating the shape to which the wafer W should be corrected, based on the information obtained by integrating the nonlinear components. FIG. 19 is a three-dimensional diagram 902 that schematically shows the shape information for correcting the nonlinear component of the distortion of the wafer W in the present embodiment. The three-dimensional diagram 902 shows the magnitude of the distortion of the wafer W in a Z direction (the direction orthogonal to the plane of the wafer W).

Subsequently, in step S25, the control device 900 calculates a drive amount of the actuator that is driven to correct the nonlinear component of the distortion of the wafer W, based on the generated shape information. The operation of the actuator to correct the nonlinear component of the distortion of the wafer W will be described in detail below. By the description above, the step of calculating the correction amount of the wafer W in step S04 in FIG. 3, is ended. Subsequently, the processing proceeds to the step of laminating the wafers W, in step S05 in FIG. 3.

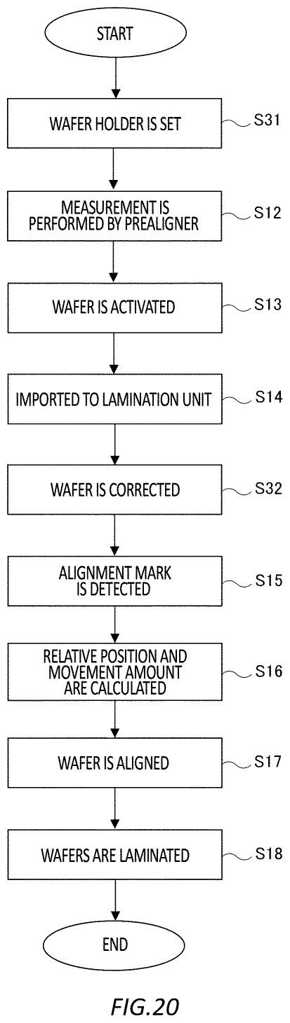

FIG. 20 is a flowchart showing a procedure for laminating the wafers W in the present embodiment. FIG. 20 shows the details of the step of laminating the wafers W, in step S05 in FIG. 3. Step S12 to step S18 in FIG. 20 are the same as step S12 to step S18 in FIG. 9, and thus the descriptions thereof will be omitted.

In step S31 of FIG. 20, the lamination control unit 150 selects the wafer holder WH from the holder stocker 400, and imports, by the conveyance unit 140, for setting, the selected wafer holder WH to the inside of the lamination unit 300 in advance. The wafer holder WH selected at this time is selected for the purpose of correcting the misalignment between the wafers W due to the linear distortion of the wafers W. The lamination control unit 150 receives, from the control device 900, the information on the linear component of the initial distortion of the wafer W measured in step S01, and the information on the linear component of the distortion during the lamination; and selects, from the holder stocker 400, based on the information, the wafer holder WH which is suitable for correcting the distortion of the linear component of the wafer W. This makes it possible to correct the linear component in the distortion of the wafer W, by the wafer holder WH.

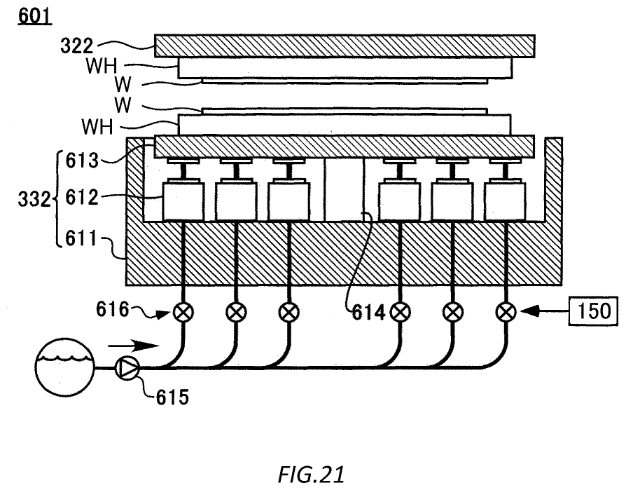

In step S32 of FIG. 20, based on the drive amount of the actuator calculated in step S25 of FIG. 17, the actuator is driven to correct the nonlinear component of the distortion of the wafer W. Hereinafter, the correction of the nonlinear component of the distortion of the wafer W will be described in detail, by using FIG. 21 to FIG. 23. Step S32 in FIG. 20 is performed between step S14 and step S15 in FIG. 9.

FIG. 21 is a schematic cross-sectional view of the substrate correction device 601 which can be used in a case of correcting the nonlinear component of the distortion of the wafer W in the present embodiment. The substrate correction device 601 is incorporated into the moving stage 332 of the lamination unit 300, and is used to correct one wafer W in the lamination device 200. The substrate correction device 601 suctions the wafer W in a state in which a shape of a suction surface for deforming the wafer W is created, thereby causing the wafer W to be deformed to correct the nonlinear component of the distortion of the wafer W.

The substrate correction device 601 has a base 611, a plurality of actuators 612, and a suction unit 613. The base 611 supports the suction unit 613 via the actuator 612. The suction unit 613 has a suction mechanism of a vacuum chuck, an electrostatic chuck, or the like, and forms an upper surface of the moving stage 332. The suction unit 613 suctions and holds the imported wafer holder WH. It should be noted that although not shown in FIG. 21, the wafer holder WH for holding the lower wafer W has a convex shape as shown in FIG. 8.

The plurality of actuators 612 are arranged below the suction unit 613 along a lower surface of the suction unit 613. In addition, the plurality of actuators 612 are driven individually by a working fluid being supplied through a pump 615 and a valve 616 from the outside under the control of the lamination control unit 150. In this manner, the plurality of actuators 612 individually expands or contracts in the thickness direction of the moving stage 332, that is, the overlaying direction of the wafer W, with different expansion and contraction amounts, to raise or lower the region of the suction unit 613 to which the plurality of actuators 612 are connected.

In addition, the plurality of actuators 612 are each connected to the suction unit 613 via links. The center portion of the suction unit 613 is connected to the base 611 by a support column 614. When the actuator 612 is operated in the substrate correction device 601, the front surface of the suction unit 613 is displaced in the thickness direction, for each region to which the actuator 612 is connected.

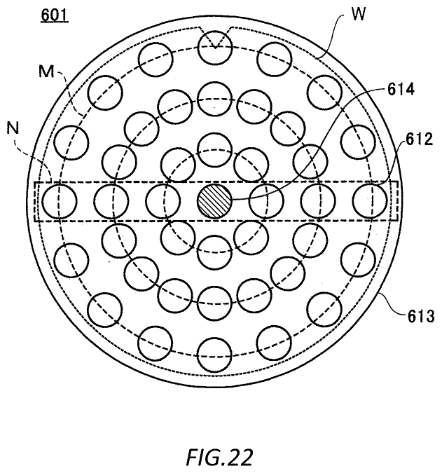

FIG. 22 is a schematic plan view of the substrate correction device 601 in the present embodiment, and is a diagram showing a layout of the actuator 612 in the substrate correction device 601. In the substrate correction device 601, the actuators 612 are arranged in a radial manner around the support column 614. In addition, the arrangement of the actuators 612 can also be regarded to be concentric with the support column 614 as the center. The arrangement of the actuators 612 is not limited to the illustrated ones, but the arrangement in, for example, a grate or spiral manner or the like is also possible. In this manner, the wafer W can also be corrected by changing the shape in concentric, radial, spiral manners, or the like.

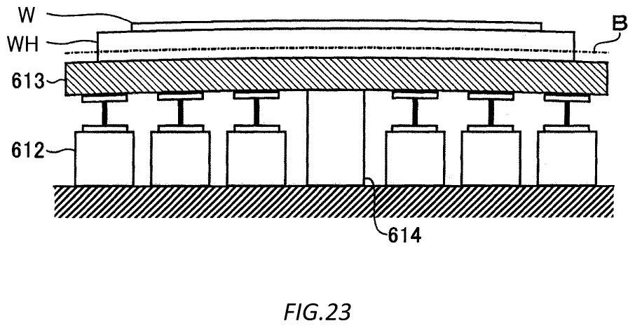

FIG. 23 is a diagram describing an operation of the substrate correction device 601 in the present embodiment. As illustrated, the shape of the suction unit 613 can be changed, by individually opening and closing the valves 616 to cause the actuators 612 to expand and contract. Therefore, in a state in which the suction unit 613 is suctioning the wafer holder WH and the wafer holder WH is holding the wafer W, the shapes of the wafer holder WH and the wafer W can be changed to be curved by changing the shape of the suction unit 613.

As shown in FIG. 22, the actuators 612 can be regarded to be arranged in a concentric manner, that is, in the circumferential direction of the moving stage 332. Therefore, as indicated by the dotted line M in FIG. 22, by grouping the actuators 612 at the same distance from the center together and increasing the drive amounts toward the circumferential edge, the center area of the front surface of the suction unit 613 is raised in such a manner that the shape of the front surface of the suction unit 613 can be changed into a spherical surface, a paraboloid surface, a cylindrical surface, or the like. In addition, the drive amounts may be controlled in such a manner that the actuators 612 indicated by the dotted line N in FIG. 22 may be grouped together and the drive amounts increase toward the circumferential edge.

In this manner, the shape of the wafer W can be changed to be curved along a spherical surface, a paraboloid surface, or the like, similar to the case where the wafer W is held by the curved wafer holder WH. Therefore, the substrate correction device 601 changes the shape in such a manner that, in the upper surface of the wafer W in the figure, the front surface of the wafer W spreads in the surface direction relative to a center portion B in the thickness direction of the wafer W, indicated with the one dot chain line in FIG. 23.

In addition, in the lower surface of the wafer W in the figure, the shape is changed in such a manner that the front surface of the wafer W contracts in the surface direction. Further, by individually controlling the expansion and contraction amount of the plurality of actuators 612, for the nonlinear shape, the shape of the wafer W can also be changed to be curved to the other shape such as the cylindrical surface, or a shape including a plurality of bump and indentation portions. As described above, by individually controlling the drive amount of the actuators 612 of the substrate correction device 601, it is possible to correct the nonlinear component of the distortion of the wafer W. By the description above, the step of correcting the nonlinear component of the distortion of the wafer W in step S31 of FIG. 20, is ended. The wafer W in which the nonlinear component of the distortion is corrected is then laminated (S18).

As described above, with the substrate processing system 1000 in the present embodiment, before the wafer W is imported to the lamination device 200, the first number of the alignment marks 218 of the wafer W are measured to measure the initial distortion of the wafer W. Then, based on the information on the initial distortion of the wafer W and the information on the distortion during the lamination, the correction amount for the distortion of the wafer W, or the misalignment between the wafers W which occurs due to the distortion, is calculated; and the actuator 612 corrects the distortion of the wafer W, or the misalignment between the wafers W which occurs due to the distortion. In this manner, there is no need to measure the distortion of the wafer W in the lamination device 200, and the lamination device 200 only needs to measure the second number of the alignment marks 218, which is less than the first number, to align the wafer W, and it is possible to reduce the number of the alignment marks 218 of the wafer W which should be measured in the lamination device 200.

In the above embodiment, the linear component of the distortion of the wafer W is corrected by using the wafer holder WH, and the nonlinear component of the distortion of the wafer W is corrected by controlling the actuator 612; however, the embodiment is not limited to this, and both of the linear component and the nonlinear component of the distortion of the wafer W may be corrected by using the wafer holder WH. In this case, for a portion of the distortion of the nonlinear component of the wafer W which cannot be completely corrected by the wafer holder WH, the correction may be supplementarily performed by using the actuator 612 of the substrate correction device 601. Further, the distortion of the linear component of the wafer W may be supplementarily corrected by using the actuator 612 of the substrate correction device 601. Each of the actuator 612 and the wafer holder WH takes a role as a correction unit which corrects the misalignment between the wafers W, and also serves as a deformation unit which deforms the wafer W.

In the above embodiment, the distortion of the wafer W during the lamination is measured by observing, by the microscopes 324, 334, the alignment marks 218 of the wafer W of the laminated body 230 actually laminated; however, the embodiment is not limited to this, and the distortion of the wafer W during the lamination may be estimated by a simulation, based on the information on the initial distortion of the wafer measured by the measurement device 100. This makes it possible to omit the processing of actually measuring the distortion of the wafer W during the lamination. In addition, in the distortion correction at a time of a first bonding of the wafer W (bonding for measuring the distortion during the lamination), the correction may be performed by referring to data accumulated in the past.

In the above embodiment, the measurement device 100 measures the first number of the alignment marks 218. However, among the alignment marks 218 on the wafer W, for example, only the alignment mark 218 in a range in which the distortion of the nonlinear component occurs, may be measured. The range in which the distortion of the nonlinear component occurs on the wafer W, may be calculated in advance and subjected to machine learning. In addition, only the alignment mark 218 at a location on the wafer W where reproducibility of the nonlinear distortion is poor (a location where it is needed to check the wafer W every time) may be measured. Further, the alignment mark 218 to be measured may be selected according to the correction capability of the substrate correction device 601 (for example, the shape that can be corrected by the actuator type). The alignment marks 218 to be measured may be determined according to the number and positions of the actuators 612 or the suction units 613 of the substrate correction device 601. In this case, the determination may be made in consideration of the center and surroundings of the actuator 612 or the suction unit 613, the range affected by the drive of the actuator 612, or the like. Further, the number of the alignment marks 218 to be measured may be reduced evenly on the wafer in whole.

In the above embodiment, the correction amount for the distortion of the wafer W is calculated based on the information on the initial distortion of the wafer W and the information on the distortion during the lamination; however, the embodiment is not limited to this, and the correction amount for the distortion of the wafer W may be calculated based only on the information on the initial distortion of the wafer W. In addition, the correction amount for the distortion of the wafer W may be calculated by using a predicted variation amount in the distortion during the lamination (the variation amount in the distortion during the lamination is predicted from the prior information on manufacturing of the wafer W, or a warpage amount of the wafer W). In addition, the component of the distortion to be corrected may be an orthogonal component (the linear component), other than the magnification nonlinear component.

In the above embodiment, the lamination control unit 150 may take account of the shape of the wafer holder WH which is selected in step S31 of FIG. 20, in calculating the movement amount of the moving stage 332.

In the above embodiment, regarding order of driving the substrate correction device 601, importing the wafer holder WH to the lamination device 200, importing the wafer W to the lamination device 200, and suctioning and holding by the substrate correction device 601, order may be various. For example, the following may be performed in order.

1. For example, in a state in which the suction surface of the substrate correction device 601 is flat, the wafer holder WH may be suctioned and held by the substrate correction device 601, and subsequently, the substrate correction device 601 may be driven to create the shape of the suction surface, thereby deforming the wafer holder WH by the frictional force between the suction surface of the substrate correction device 601 and the wafer holder WH; and then the wafer W may be imported to the lamination device 200, and the wafer W may be suctioned by the wafer holder WH, thereby deforming the wafer W along the shape of the wafer holder WH.

2. in a state in which the substrate correction device 601 is driven in advance to create the shape of the suction surface, the wafer holder WH may be imported to the lamination device 200 to be suctioned and held, thereby deforming the wafer holder WH along the shape of the suction surface; and finally, the wafer W may be imported and suctioned by the wafer holder WH, thereby deforming the wafer W along the shape of the wafer holder WH.

3. in a state in which the substrate correction device 601 is driven in advance to create the shape of the suction surface, the wafer W suctioned by the wafer holder WH may be imported to the lamination device 200 at the same time, and the wafer holder WH may be suctioned and held by the substrate correction device 601, thereby deforming both of the wafer W and the wafer holder WH along the shape of the suction surface.

4. In a state in which the suction surface of the substrate correction device 601 is flat, the wafer W suctioned by the wafer holder WH may be imported to the lamination device 200, the wafer holder WH may be suctioned and held by the substrate correction device 601, and subsequently, the substrate correction device 601 may be driven to create the shape of the suction surface, thereby deforming the wafer W and the wafer holder WH by the frictional force between the suction surface of the substrate correction device 601 and the wafer holder WH; and the shapes of the wafer holder WH and the wafer W may be corrected.

It should be noted that in 3. and 4. described above, after the wafer W and the wafer holder WH are deformed, the wafer W suctioned by the wafer holder WH may be released, thereby releasing the deformation of the wafer W once, and causing the wafer W to be suctioned on the wafer holder WH again.

In addition, as in 2. and 3. described above, in a state in which the shape of the suction surface of the substrate correction device 601 is created, when the wafer W is imported into the lamination device 200, the EGA calculation may be performed based on the information in relation to the nonlinear component of the distortion of the wafer W measured by the measurement device 100 and the positional information of the plurality of alignment marks 218 of the wafer W measured in the lamination device 200.

In the above embodiment, when the plurality of wafers W are bonded successively as a first set, a second set, . . . an Xth set, for a method for calculating the correction amount for the distortion of the wafers W, there are methods of the following (1) to (3). (1) First, the first set is laminated, and the correction amount for the distortion of the second set of the wafers W is calculated from the nonlinear component of the distortion, during the lamination, of the first set of the wafers W obtained by the lamination device 200; and the nonlinear component of the initial distortion of the second set of the wafers W obtained by the measurement device 100. (2) The correction amount for the distortion of the first set of the wafers W is calculated from the nonlinear component of the initial distortion of the first set of the wafers W obtained by the measurement device 100; and the nonlinear component of the distortion of the wafer W during the lamination, estimated from the data of the wafers of the same type or the similar type, in the past. (3) The nonlinear component of the distortion of the wafer W during the lamination is estimated from the nonlinear component and the linear component of the initial distortion of the first set of the wafers W obtained by the measurement device 100; and the correction amount for the distortion of the first set of the wafers W is calculated by using both.

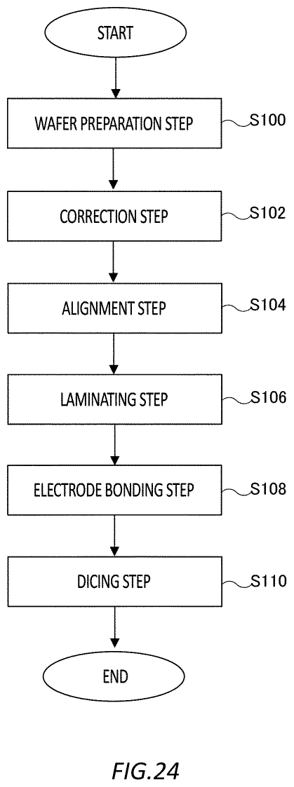

FIG. 24 is a flowchart showing a semiconductor device manufacturing method of a lamination type. This manufacturing method has steps S100, S102, S104, S106, and S108. The semiconductor device is, for example, an electronic component such as an image capturing element such as a back-illuminated image capturing element, or a memory such as a flash memory. The semiconductor device is, for example, a chip component (an electronic component) obtained by dicing a laminated body in which a pixel substrate on which pixels are arranged; and a processing substrate on which a processing circuit such as an amplifier circuit, an image processing circuit, and a control circuit is arranged, are laminated. It should be noted that the semiconductor device of a lamination type is not limited to a back-illuminated image capturing element, and may be, for example, a processing element or the like obtained by laminating and dicing a memory substrate and a logic substrate.

S100: This is a wafer preparation step of preparing a predetermined number of the wafers W on which a plurality of semiconductor devices are formed. In the present step, as described in relation to FIG. 2, a semiconductor exposure device is used to reduce and project a circuit pattern on a mask, onto a wafer coated with a resist; and after the resist is developed, etching or thermal diffusion processing of an impurity is performed to obtain the wafer W on which a circuit element is formed.

S102: This is a correction step of correcting the distortion of at least one of the wafers W to be overlaid on top of each other, or the misalignment between the wafers W which occurs due to the distortion. In the present step, the corrections described in relation to FIG. 3 to FIG. 23, is performed. For example, steps S01 to S04 in FIG. 3, steps S21 to S25 in FIG. 17, and steps S31 to S32 in FIG. 20 are performed.

S104: This is an alignment step of performing the alignment between the wafers W which should be overlaid on top of each other. In the present step, the alignment described in relation to FIG. 3 to FIG. 23, is performed. For example, step S05 in FIG. 3, and steps S15 to S17 in FIG. 20 are performed.

S106: This is a laminating step of laminating the wafers W which are aligned. In the present step, the lamination described in relation to FIG. 3 to FIG. 23 is performed to obtain the laminated body 230. For example, step S05 in FIG. 3, and step S18 in FIG. 20 are performed. The laminated body 230 is conveyed by a robot arm from the lamination device 200 to an electrode bonding performing unit (not shown).

S108: This is an electrode bonding step of bonding the connection terminals to each other on the wafers which are overlaid on top of each other. In the present step, the laminated body 230 which is aligned and laminated, is imported to an annealing furnace and heat-treated. By applying a predetermined amount of heat for a predetermined period of time, the connection terminals (metal bumps and pads, and metal bumps and metal bumps) on the wafer W are bonded. It should be noted that step S106 and step S108 may be collectively referred to as a bonding step. In addition, if a bonding strength and an electrical connection are sufficiently obtained in step S106, step S108 may be omitted.

The correction step (S012), the alignment step (S104), the laminating step (S106), and the electrode bonding step (S108) that are described above, are repeated by the same number of times as the number of the wafers W which should be laminated (the predetermined number described above). Depending on the case, after the lamination and the bonding, a step of thinning the laminated body 230 by grinding, polishing, or etching, or the like may be added. In this manner, the laminated body 230 which is formed by laminating a predetermined number of the wafers, is obtained.

S110: This is a dicing step of separating individual semiconductor devices by cutting, from the laminated body 230 which is formed by laminating a predetermined number of the wafers W. In the present step, the wafer W which is laminated and bonded at a wafer level is cut along the scribe line 212, and is cut into the chip for each circuit region 216. For the cutting, the following methods are usually adopted: a dicing saw method using a dicing blade for the cutting; a method using a laser beam to melt the front surface of the wafer for the cutting; or a method using a diamond cutter to draw a cutting line for the cutting. Among these, in particular, the dicing saw method is preferable as a method for separating the laminated body 230 into the chips. The individual chip separated by the cutting in this way is the semiconductor device of a lamination type.

It should be noted that in the above embodiment, the measurement device 100 may have a reference coordinate system, and measure absolute coordinates of the alignment mark 218 of the wafer W in the reference coordinate system. The measurement device 100 may detect the absolute coordinates of another mark on the wafer W, other than the alignment mark 218. When the target to be measured is the laminated body, the measurement device 100 may measure the absolute coordinates of the alignment mark 218 of at least one wafer W of the plurality of wafers W which constitutes the laminated body, and calculate the positional information. The measurement device 100 may send the calculated positional information of the alignment mark 218 to an exposure device which exposes the pattern onto at least one wafer W of the laminated body, and the exposure device may perform exposure processing based on the received positional information. Information in relation to a measurement result of the laminated body measured by the measurement device 100, may be sent from the measurement device 100 to an exposure device which exposes the pattern onto at least one of a plurality of other wafers W to be bonded thereafter, and the exposure device may perform the exposure processing on the wafer W based on the sent information. As described above, when the measurement information of the laminated body is fed forward to the exposure device which further performs the exposure processing on the laminated body, as well, or when the feedback is made to the exposure device which performs the exposure processing on the wafer W to be bonded thereafter, as well, the information that is sent from the measurement device 100 to the exposure device is not limited to the positional information of the alignment mark 218, but may also additionally include: at least one of the misalignment information of the mark from the design value; the misalignment information between the plurality of wafers W which are laminated; or the information in relation to the distortion, the warpage, or the like of at least one of the plurality of wafers W which are laminated.

While the present invention has been described with the embodiments, the technical scope of the present invention is not limited to the above-described embodiments. It is apparent to persons skilled in the art that various alterations and improvements can be added to the above-described embodiments. It is also apparent from the scope of the claims that the embodiments added with such alterations or improvements can be included in the technical scope of the present invention.

The operations, procedures, steps, stages, or the like of each process performed by a device, system, program, and method shown in the claims, embodiments, or diagrams can be realized in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

### EXPLANATION OF REFERENCES

60: measurement control unit; 100: measurement device; 101: measurement unit; 102: wafer slider; 103: drive system; 104: measurement control unit; 110: housing; 120, 130 wafer cassette; 140: conveyance unit; 150: control unit; 200: lamination device; 212: scribe line; 214: notch; 216: circuit region; 218: alignment mark; 225: holding surface; 230: laminated body; 300: lamination unit; 301: floor surface; 310: frame body; 312: bottom plate; 314: support column; 316: ceiling plate; 322: fixed stage; 324, 334: microscope; 331: X direction drive unit; 332: moving stage; 333: Y direction drive unit; 335: Z direction drive unit; 400: holder stocker; 500: prealigner; 600: activation device; 601: correction device; 611: base; 612 actuator; 613 suction unit; 614 support column; 615: pump; 616 valve; 1000: substrate processing system; W: wafer; WH: wafer holder.

### Other Possible Claims

### (Item 1)

A substrate correction device including:
an acquisition unit which acquires first information based on positional information of a plurality of alignment marks on a first substrate, the alignment marks being measured externally; and
a stage which holds a second substrate to be bonded to the first substrate,
wherein
the stage has a deformation unit which deforms the second substrate, and
the deformation unit is controlled based on the first information.

### (Item 2)

The substrate correction device according to item 1, including:
a holding member which has a holding surface for holding the first substrate, wherein
when the first substrate and the second substrate are bonded to each other, the first substrate held by the holding member is released.

### (Item 3)

The substrate correction device according to item 1 or 2, wherein the deformation unit is able to partially deform the second substrate.

### (Item 4)

The substrate correction device according to any one of items 1 to 3, wherein the deformation unit has a plurality of actuators arranged along the second substrate.

### (Item 5)

A substrate correction device including:
an acquisition unit which acquires first information based on positional information of a plurality of alignment marks on a first substrate, the alignment marks being measured externally; and
a measurement unit which measures the positional information of the plurality of alignment marks of the first substrate, and outputs second information based on the positional information;
a stage which holds a second substrate to be bonded to the first substrate;
a deformation unit which deforms the second substrate held by the stage; and
a control unit which controls the deformation unit based on the first information, and aligns the first substrate and the second substrate based on the second information.

### (Item 6)

A substrate correction device including:
an acquisition unit which acquires first information based on positional information of a plurality of alignment marks on a substrate, the alignment marks being measured externally;
a stage which holds the substrate;
a correction unit which corrects a misalignment between the substrate held by the stage, and another substrate to be bonded to the substrate; and
a control unit which controls the correction unit based on the first information.

### (Item 7)

The substrate correction device according to item 6, further including:
a measurement unit which measures the positional information of the plurality of alignment marks of the substrate, in a state in which the substrate is placed on the stage, and outputs second information based on the measured positional information, wherein
the control unit aligns the substrate with the another substrate based on the second information.

### (Item 8)

The substrate correction device according to item 7, wherein a number of the plurality of alignment marks that are measured by the measurement unit, is less than a number of the plurality of alignment marks measured externally.

### (Item 9)

The substrate correction device according to item 7 or 8, wherein the control unit sets a parameter that is used for aligning the substrate and the another substrate, based on the second information measured by the measurement unit.

### (Item 10)

The substrate correction device according to any one of items 6 to 9, wherein the first information includes information on a linear component and a nonlinear component of a distortion of the substrate.

### (Item 11)

The substrate correction device according to any one of items 6 to 10, wherein when the substrate is laminated on the another substrate, the control unit controls the correction unit based on third information in relation to a distortion that occurs in at least one of the substrate or the another substrate.

### (Item 12)

The substrate correction device according to any one of items 6 to 11, wherein among the alignment marks on the substrate, a first measurement unit measures the positional information of the alignment mark in a range in which the misalignment occurs due to a distortion of a nonlinear component that occurs on at least one of the substrate or the another substrate.

### (Item 13)

The substrate correction device according to any one of items 10 to 12, further including:
a holding member which has a holding surface for holding the substrate, wherein
the holding surface has a convex shape in which a center is raised toward the substrate.

### (Item 14)

The substrate correction device according to any one of items 10 to 13, further including:
a holding member which has a holding surface for holding the substrate, wherein
the holding surface has a region with a different height in a circumferential direction.

### (Item 15)

The substrate correction device according to any one of items 6 to 14, wherein the correction unit is a plurality of actuators arranged on one surface of the substrate.

### (Item 16)

A substrate lamination device including:
the substrate correction device according to any one of items 6 to 15; and
a lamination unit which laminates the substrate on another substrate.

### (Item 17)

A substrate processing system including:
a first measurement unit which measures positional information of a plurality of alignment marks on a substrate placed on a first stage, and outputs first information based on the measured positional information;
a correction unit which corrects a misalignment between the substrate held by a second stage, and another substrate to be bonded to the substrate; and
a control unit which controls the correction unit based on the first information.

### (Item 18)

The substrate processing system according to item 17, including:
a second measurement unit which measures positional information of a number of the alignment marks, the number being less than a number of the alignment marks that are measured by the first measurement unit, and outputs second information based on the measured positional information, wherein
the control unit controls the correction unit based on the first information, and controls an alignment of the substrate with another substrate based on the second information.

### (Item 19)

A substrate processing system including:
a first measurement unit which measures positional information of a plurality of alignment marks on a substrate placed on a first stage, and outputs first information based on the measured positional information;
a second measurement unit which measures positional information of a plurality of alignment marks of the substrate held by a second stage, and outputs second information based on the positional information;
a correction unit which corrects a misalignment between the substrate held by the second stage, and another substrate to be bonded to the substrate; and
a control unit which controls the correction unit based on the first information,
wherein
a number of the alignment marks that are measured by the second measurement unit is less than a number of the alignment marks that are measured by the first measurement unit.

### (Item 20)

A substrate processing system including:
a measurement unit which measures positional information of a plurality of alignment marks on a substrate placed on a first stage, and outputs first information based on the measured positional information;
a correction unit which corrects a misalignment between the substrate held by a second stage, and another substrate to be bonded to the substrate; and
a control unit which controls the correction unit based on the first information,
wherein
the measurement unit has a reference coordinate system, and measures absolute coordinates of the alignment mark in the reference coordinate system.

### (Item 21)

A substrate correction method including:
acquiring first information based on positional information of a plurality of alignment marks on a substrate; and
correcting a misalignment between the substrate held by a stage, and another substrate to be bonded to the substrate; and
controlling the correcting based on the first information.

### (Item 22)

The substrate correction method according to item 21, further including: measuring the positional information of the plurality of alignment marks of the substrate, in a state in which the substrate is placed on the stage, and outputting second information based on the measured positional information, wherein

in the controlling, the substrate and the another substrate are aligned with each other based on the second information.

### (Item 23)

The substrate correction method according to item 22, wherein a number of the plurality of alignment marks that are measured in the measuring, is less than a number of the plurality of alignment marks measured externally.

### (Item 24)

A substrate processing method including:
measuring positional information of a plurality of alignment marks on a substrate placed on a first stage, and outputting information based on the measured positional information;
correcting a misalignment between the substrate placed on a second stage, and another substrate to be bonded to the substrate; and
controlling the correcting based on the information acquired in the measuring.

### (Item 25)

A semiconductor device manufacturing method including:
aligning the substrate corrected by the substrate correction method according to any one of items 21 to 23, and another substrate with each other;
bonding the substrate and the another substrate to each other to form a laminated body; and
dicing in which the laminated body is cut to be separated into a plurality of semiconductor devices.

### (Item 26)

A substrate correction device including:
an acquisition unit which acquires first information based on positional information of a plurality of alignment marks on a substrate, the alignment marks being measured externally;
a stage which holds the substrate;
a deformation unit which deforms the substrate held by the stage; and
a control unit which controls the deformation unit based on the first information.

What is claimed is:

1. A substrate correction device comprising:
an acquisition unit which acquires first information based on positional information of a plurality of alignment marks on a first substrate, the alignment marks being measured externally; and
a stage which holds a second substrate to be bonded to the first substrate, wherein
the stage has a deformation unit which deforms the second substrate, and
the deformation unit is controlled based on the first information.

2. The substrate correction device according to claim 1, comprising:
a holding member which has a holding surface for holding the first substrate, wherein
when the first substrate and the second substrate are bonded to each other, the first substrate held by the holding member is released.

3. The substrate correction device according to claim 1, wherein the deformation unit is able to partially deform the second substrate.

4. The substrate correction device according to claim 1, wherein the deformation unit has a plurality of actuators arranged along the second substrate.

5. The substrate correction device according to claim 1, comprising:
a measurement unit which measures the positional information of the plurality of alignment marks of the first substrate, and outputs second information based on the positional information; and
a control unit which controls the deformation unit based on the first information, and aligns the first substrate and the second substrate based on the second information, wherein
the deformation unit deforms the second substrate held by the stage.

6. A substrate correction device comprising:
an acquisition unit which acquires first information based on positional information of a plurality of alignment marks on a substrate, the alignment marks being measured externally;
a stage which holds the substrate;
a correction unit which corrects a misalignment between the substrate held by the stage, and another substrate to be bonded to the substrate; and
a control unit which controls the correction unit based on the first information.

7. The substrate correction device according to claim 6, further comprising:
a measurement unit which measures the positional information of the plurality of alignment marks of the substrate, in a state in which the substrate is placed on the stage, and outputs second information based on the measured positional information, wherein
the control unit aligns the substrate with the another substrate based on the second information.

8. The substrate correction device according to claim 7, wherein a number of the plurality of alignment marks that are measured by the measurement unit, is less than a number of the plurality of alignment marks measured externally.

9. The substrate correction device according to claim 7, wherein the control unit sets a parameter that is used for aligning the substrate and the another substrate, based on the second information measured by the measurement unit.

10. The substrate correction device according to claim 6, wherein the first information includes information on a linear component and a nonlinear component of a distortion of the substrate.

11. The substrate correction device according to claim 6, wherein when the substrate is laminated on the another substrate, the control unit controls the correction unit based on third information in relation to a distortion that occurs in at least one of the substrate or the another substrate.

12. The substrate correction device according to claim 6, wherein among the alignment marks on the substrate, a first measurement unit measures the positional information of the alignment mark in a range in which the misalignment occurs due to a distortion of a nonlinear component that occurs on at least one of the substrate or the another substrate.

13. The substrate correction device according to claim 10, further comprising:
a holding member which has a holding surface for holding the substrate, wherein
the holding surface has a convex shape in which a center is raised toward the substrate.

14. The substrate correction device according to claim 10, further comprising:
a holding member which has a holding surface for holding the substrate, wherein
the holding surface has a region with a different height in a circumferential direction.

15. The substrate correction device according to claim 6, wherein the correction unit is a plurality of actuators arranged on one surface of the substrate.

16. A substrate lamination device comprising:
the substrate correction device according to claim 6; and
a lamination unit which laminates the substrate on another substrate.

17. A substrate processing system comprising:
a first measurement unit which measures positional information of a plurality of alignment marks on a substrate placed on a first stage, and outputs first information based on the measured positional information;
a correction unit which corrects a misalignment between the substrate held by a second stage, and another substrate to be bonded to the substrate; and
a control unit which controls the correction unit based on the first information.

18. The substrate processing system according to claim 17, comprising:
a second measurement unit which measures positional information of a number of the alignment marks, the number being less than a number of the alignment marks that are measured by the first measurement unit, and outputs second information based on the measured positional information, wherein
the control unit controls the correction unit based on the first information, and controls an alignment of the substrate with another substrate based on the second information.

19. The substrate processing system according to claim 17, comprising
a second measurement unit which measures positional information of a plurality of alignment marks of the substrate held by a second stage, and outputs second information based on the positional information, wherein
a number of the alignment marks that are measured by the second measurement unit is less than a number of the alignment marks that are measured by the first measurement unit.

20. The substrate processing system according to claim 17, wherein
the first measurement unit has a reference coordinate system, and measures absolute coordinates of the alignment mark in the reference coordinate system.

21. A substrate correction method comprising:
acquiring first information based on positional information of a plurality of alignment marks on a substrate; and
correcting a misalignment between the substrate held by a first stage, and another substrate to be bonded to the substrate; and
controlling the correcting based on the first information.

22. The substrate correction method according to claim 21, further comprising:
measuring the positional information of the plurality of alignment marks of the substrate, in a state in which the substrate is placed on the first stage, and outputting second information based on the measured positional information, wherein
In the controlling, the substrate and the another substrate are aligned with each other based on the second information.

23. The substrate correction method according to claim 22, wherein a number of the plurality of alignment marks that are measured in the measuring, is less than a number of the plurality of alignment marks measured externally.

24. The substrate correction method according to claim 21, wherein
in the acquiring, the positional information of the plurality of alignment marks on the substrate placed on a second stage which is different from the first stage is measured, and the first information based on the measured positional information is acquired.

25. A semiconductor device manufacturing method comprising:
aligning the substrate corrected by the substrate correction method according to claim 21 and another substrate with each other;
bonding the substrate and the another substrate to each other to form a laminated body; and
dicing in which the laminated body is cut to be separated into a plurality of semiconductor devices.

26. A substrate correction device comprising:
an acquisition unit which acquires first information including information on a nonlinear component of a distortion of a first substrate, the first information being based on positional information of a plurality of alignment marks on a first substrate, the positional information being obtained by measuring the plurality of alignment marks on the first substrate by a measurement device;
a stage which holds one substrate of the first substrate or a second substrate to be bonded to the first substrate;
a measurement unit which measures a plurality of alignment marks on the one substrate;
a deformation unit which deforms the one substrate held by the stage; and
a control unit which controls the deformation unit based on the first information, and controls a position of the stage based on second information based on the positional information of the plurality of alignment marks on the one substrate, the positional information being obtained by measuring the plurality of alignment marks on the one substrate by the measurement unit, wherein
a number of the plurality of alignment marks that are measured by the measurement unit is less than a number of the plurality of alignment marks that are measured by the measurement device.
